(19) United States
(12) Patent Application Publication
(10) Pub. No.: US 2011/0017501 A1
(43) Pub. Date: Jan. 27, 2011

(54) COMPOSITE MATERIAL AND MANUFACTURING METHOD THEREOF

(76) Inventors: Tadahiro Ohmi, Miyagi (JP); Akinobu Teramoto, Miyagi (JP); Masayuki Ishizuka, Tokyo (JP); Nobuhiro Hidaka, Tokyo (JP); Yasushi Shirakata, Tokyo (JP)

Correspondence Address: MORGAN LEWIS & BOCKIUS LLP, 1111 PENNSYLVANIA AVENUE NW, WASHINGTON, DC, 20004, US

(21) Appl. No.: 12/935,662

(22) PCT Filed: Mar. 26, 2009
(86) PCT No.: PCT/JP2009/056167

§ 371 Date: Sep. 30, 2010

(30) Foreign Application Priority Data
Apr. 4, 2008 (JP) 2008-097762

(51) Int. Cl. H05K 1/00; B32B 5/16; B32B 5/00; B05D 7/00; B05D 3/12

(52) U.S. Cl. 174/258; 428/323; 428/328; 428/330; 428/98; 428/329; 427/213.3

(57) ABSTRACT

This invention provides a composite material useful for size reduction of electronic components and circuit boards mounted on electronic equipment and exhibiting a low magnetic loss (tan δ), and a manufacturing method thereof. The composite material contains an insulating material and particulates dispersed in this insulating material, the particulates being previously coated with an insulating material having substantially the same composition as that of the coating insulating material. The particulates consist of an organic or inorganic substance and preferably have a flat shape. The insulating material may be an insulating material commonly used in the field of electronic components. The composite material of the invention is preferably manufactured by a manufacturing method in which the particulates are previously coated with an insulating material and dispersed in an insulating material having substantially the same composition as that of the coating insulating material. The composite material of the invention can be applied as a material for circuit boards and/or electronic components to realize further reduction in size and power consumption of information and telecommunication equipment in a frequency band of several hundred MHz to 1 GHz.

### TECHNICAL FIELD

This invention relates to a composite material for use as a substrate material for high-frequency devices, having particulates dispersed in an insulating material, and also relates to a manufacturing method thereof.

### BACKGROUND ART

Along with increase in operation speed and density of information and telecommunication equipment, there has arisen a strong demand for reduction in size and power consumption of electronic components and circuit boards mounted on electronic equipment. In general, a wavelength λg of electromagnetic waves propagated in a material can be represented by the following equation, using a wavelength λ0 of electromagnetic waves propagated in vacuum, a real part εr′ of a complex permittivity of the material (hereafter, referred to as the relative permitivity εr), and a real part μr′ of a complex permeability of the material (hereafter, referred to as the relative permeability μr).

λg=λ0/(εr·μr)^{1/2}

Therefore, it is known that as the relative permittivity cr and relative permeability pr become greater, the wavelength shortening ratio becomes greater, which makes it possible to reduce the size of electronic components and circuit boards. Thus, recently, efforts have been made to obtain electronic components or circuit boards with excellent characteristics, by using a paste in which powder is mixed with an organic vehicle, or a composite material in which powder is composited with a resin material, instead of using the powder alone. For example, magnetic powder having good high-frequency characteristics is mixed with and dispersed in a resin to form a composite material, and this composite material is used to provide electronic components or circuit boards having high magnetic properties.

However, in a high-frequency zone used by information and telecommunication equipment or the like, eddy current is generated on the surface of a magnetic material, and this eddy current generates a magnetic field in a direction cancelling the variation in an applied magnetic field, which causes apparent reduction of magnetic permeability of the material. In addition, since increase in the eddy current causes energy loss due to Joule's heat, it is conventionally difficult to use the aforementioned composite material as a material for circuit boards or electronic components. In order to reduce the eddy current, it is effective to set the diameter of the magnetic powder smaller than the skin depth d represented by the following equation.

d=1/(π·f·μ0·μr·σ)^{1/2}

In the above equation, f indicates a signal frequency, a indicates a conductivity of the magnetic powder, and μ0 indicates a magnetic permeability of a vacuum.

The size of the magnetic powder dispersed in a resin, as described above, has been reduced with the development of nanotechnology. However, no technology for uniformly dispersing fine particulates in a resin has been established, and the particulates are apt to form an aggregate in the resin. An aggregate in a composite material behaves as one large magnetic particle.

Therefore, eddy current is apt to be generated at a high frequency, inducing reduction of relative permeability and increase of energy loss. The powder used in such a composite material is required to have not only good characteristics but also good dispersibility to resin materials.

In addition, examples have been reported of manufacture of insulating magnetic powder in which magnetic powder is formed with an insulating coating in order to prevent the contact between magnetic powder particles in the resin and to reduce the eddy current.

Manufacturing methods of such insulating magnetic powder are disclosed in several prior art documents, including, for example, Patent Document 1 disclosing a method of coating the surface of magnetic powder with an insulating inorganic material by using mechanical impact force, and Patent Document 2 disclosing a method of making a solid mixture by drying a mixture of magnetic powder and insulating inorganic powder.

On the other hand, Patent Document 3 discloses a composite material having a high permittivity in which an inorganic filler is dispersed in an organic resin, the inorganic filler being obtained by insulating and surface-treating metal powder with an oxide such as silicon, boron, or phosphorus, or with a titanium-barium-neodymium based, titanium-barium-tin based, or titanium-barium-strontium based oxide having a dielectric property, and further with a magnetic oxide such as Mn—Zn based ferrite, Ni—Zn based ferrite, or Mn—Mg—Zn based ferrite.

According to Patent Document 4, an inorganic filler having a spherical shape with a particle size of 45 to 100 μm is dispersed in a resin in order to reduce the hysteresis loss, that is a loss of the magnetic material. For this purpose, the surface of the inorganic filler is previously surface-treated with an epoxy resin, and the surface-treated inorganic filler is dispersed in the epoxy resin.

Patent Document 1: JP-A-2002-368480

Patent Document 2: JP-A-H06-260319

Patent Document 3: JP-A-2003-297634

Patent Document 4: JP-A-H02-198106

### DISCLOSURE OF THE INVENTION

### Problems to be Solved by the Invention

However, according to the method of coating the surface of an inorganic filler with an insulating inorganic material by means of a mechanical impact force as disclosed in Patent Document 1, it is difficult to enhance the bonding force between the inorganic filler and the insulating inorganic material even though the insulating properties can be improved.

Therefore, when the filler is dispersed in a solvent with an organic binder, the insulation coating will be detached by a shear force during the dispersion, and thus enough insulating properties cannot be obtained.

The approach of preparing a solid mixture as described in Patent Document 2 is also subject to similar problems. A sol-gel method using a metal alkoxide provides an insulation coating with considerably high insulating properties, but the insulation coating is not satisfactory in denseness and thickness, and another insulation coating exhibiting even higher insulating properties must be formed.

The material obtained by the method described in Patent Document 3 is a composite material in which an inorganic filler obtained through an insulating treatment and a surface treatment is dispersed in an organic resin. However, the composition of the surface coating of the inorganic filler is different from that of the organic resin, which reduces the compatibility therebetween.

Accordingly, in order to increase the relative permeability and relative permittivity of a composite material with an organic resin, an inorganic filler must be highly incorporated. However, if the aforementioned inorganic filler is highly incorporated in the resin, their poor compatibility will often lead to generation of voids during curing of the resin. Additionally, since the adhesion at the interface between inorganic particulates and the resin is low, detachment is apt to occur at the interface.

On the other hand, although Patent Document 4 mentions reduction of hysteresis loss, it does not mention reduction of eddy current. Thus, it does not provide a composite material exhibiting a low magnetic loss in a frequency band of several hundred MHz to one GHz.

This invention has been made in view of the problems described above, and it is therefore an object of the invention to provide a composite material which is useful for size reduction of electronic components and circuit boards to be mounted on electronic equipment and exhibits a low magnetic loss (tan δ), and to provide a manufacturing method of such a composite material.

### Means for Solving the Problems

As a result of earnest researches, the inventors of this invention have found that, in a composite material having particulates dispersed in an insulating material, the particulates are allowed to exhibit desirable dispersibility in the insulating material by previously coating the particulates with an insulating material having substantially the same composition as that of the aforementioned insulating material and then dispersing the coated particulates in the insulating material without drying the same.

According to a first aspect of this invention, there is provided a composite material having flat particulates dispersed in an insulating material, characterized by comprising the flat particulates which have previously been coated with an insulating material having substantially the same composition as that of the insulating material.

According to a second aspect of this invention, there is provided the composite material as recited in the first aspect, characterized in that the particulates have a thickness of 0.001 to 5 μm and a length of 0.002 to 10 μm.

According to a third aspect of this invention, there is provided a composite material having particulates with a particle size of 0.001 to 10 μm dispersed in an insulating material, characterized by comprising the particulates with the particle size which have previously been coated with an insulating material having substantially the same composition as that of the insulating material.

According to a fourth aspect of this invention, there is provided the composite material as recited in any one of the first to the third aspects, characterized in that the particulates comprise at least one selected from the group consisting of aluminum (Al), manganese (Mn), silicon (Si), magnesium (Mg), chromium (Cr), nickel (Ni), molybdenum (Mo), copper (Cu), iron (Fe), cobalt (Co), zinc (Zn), tin (Sn), silver (Ag), titanium (Ti), and zirconium (Zr).

According to a fifth aspect of this invention, there is provided the composite material as recited in any one of the first to the third aspects, characterized in that the particulates comprise at least one selected from the group consisting of nickel (Ni), permalloy (Ni—Fe), iron (Fe), iron (Fe)-silicon (Si) alloy, iron (Fe)-nitrogen (N) alloy, iron (Fe)-carbon (C) alloy, iron (Fe)-boron (B) alloy, iron (Fe)-phosphorus (P) alloy, iron (Fe)-aluminum (Al) alloy, and iron (Fe)-aluminum (Al)-silicon (Si) alloy.

According to a sixth aspect of this invention, there is provided the composite material as recited in the fourth aspect, characterized in that the particulates are metal powder having added thereto at least one or more metal elements selected from titanium (Ti), vanadium (V), chromium (Cr), manganese (Mn), cobalt (Co), copper (Cu), zinc (Zn), niobium (Nb), molybdenum (Mo), indium (In), and tin (Sn).

According to a seventh aspect of this invention, there is provided the composite material as recited in any one of the first to the third aspects, characterized in that the particulates comprise at least one selected from the group consisting of goethite (FeOOH), hematite (Fe₂O₃), magnetite (Fe₃O₄), manganese (Mn)-zinc (Zn) ferrite, nickel (Ni)-zinc (Zn) ferrite, cobalt (Co) ferrite, manganese (Mn) ferrite, nickel (Ni) ferrite, copper (Cu) ferrite, zinc (Zn) ferrite, magnesium (Mg) ferrite, lithium (Li) ferrite, manganese (Mn)-magnesium (Mg) ferrite, copper (Cu)-zinc (Zn) ferrite, and manganese (Mn)-zinc (Zn) ferrite.

According to an eighth aspect of this invention, there is provided the composite material as recited in any one of the first to the seventh aspects, characterized in that the amount of the particulates contained in the composite material is 10% or more by volume.

According to a ninth aspect of this invention, there is provided the composite material as recited in any one of the first to the eighth aspects, characterized in that the insulating material comprises a thermoplastic resin.

According to a tenth aspect of this invention, there is provided the composite material as recited in any one of the first to the eighth aspects, characterized in that the insulating material comprises a thermosetting resin.

According to an eleventh aspect of this invention, there is provided the composite material as recited in any one of the first to the tenth aspects, characterized in that the insulating material contains a synthetic resin or liquid-phase resin comprising at least one selected from polyimide resins, polybenzoxadole resins, polyphenylene resins, poly (benzocyclobutene) resins, poly (arylene ether) resins, polysiloxane resins, epoxy resins, urethane resins, polyester resins, polyester urethane resins, fluororesins, polyolefin resins, poly(cycle-olefin) resins, cyanate resins, polyphenylene ether resins, and polystyrene resins.

According to a twelfth aspect of this invention, there is provided the composite material as recited in any one of the first to the eleventh aspects, characterized in that the insulating material comprises at least one selected from the group consisting of Al₂O₃, SiO₂, TiO₂, 2MgO.SiO₂, MgTiO₃, CaTiO₃, SrTiO₃, BaTiO₃, 3Al₂O₃.2SiO₂, ZrO₂, SiC, and AlN ceramics.

According to a thirteenth aspect of this invention, there is provided the composite material as recited in any one of the first to the twelfth aspects, characterized in that, in the composite material having particulates dispersed in an insulating material, the relative permeability pr is greater than one and the loss factor tan δ is 0.05 or less at a frequency of 1 GHz.

According to a fourteenth aspect of this invention, there is provided the composite material as recited in any one of the first to the thirteenth aspects, characterized in that, in the composite material having particulates dispersed in an insulating material, the composite material has permittivities which differ between a vertical direction and a parallel direction to an electric field applied during use.

According to a fifteenth aspect of this invention, there is provided the composite material as recited in any one of the first to the fourteenth aspects, characterized in that, in the composite material having particulates dispersed in an insulating material, the composite material has a volume resistivity of 5×10⁵ Ω·cm or higher.

According to a sixteenth aspect of this invention, there is provided a manufacturing method of a composite material characterized by comprising the step of producing slurry of flat particulates the surfaces of which are coated with an insulating material by performing the step of mechanically deforming the particulates into a flat shape at the same time with the step of obtaining the flat particulates the surfaces of which are coated with the insulating material, by stirring the particulates in a solvent having the insulating material dissolved therein with the use of a dispersion medium.

According to a seventeenth aspect of this invention, there is provided a manufacturing method of a composite material characterized by comprising the step of adding, to slurry of flat particulates the surfaces of which are coated with an insulating material, an insulating material having substantially the same composition as that of the coating insulating material.

According to an eighteenth aspect of this invention, there is provided the composite material as recited in any one of the first to the fifteenth aspects, characterized by being manufactured by a manufacturing method comprising the steps of: obtaining the particulates coated with an insulating material by stirring the particulates in a solvent having the insulating material dissolved therein; dispersing the obtained particulates coated with the insulating material in an insulating material having substantially the same composition as that of the coating insulating material; and applying a mechanical force to the particulates to deform the particulates into a flat shape by using a dispersion medium when stirring the particulates in the solvent having the insulating material dissolved therein.

According to a nineteenth aspect of this invention, there is provided an electronic component characterized by comprising at least a composite material as recited in any one of the first to the fifteenth aspects, and the eighteenth aspect.

According to a twentieth aspect of this invention, there is provided an electronic component characterized by comprising at least a composite material produced by the manufacturing method as recited in the sixteenth or the seventeenth aspects.

According to a twenty-first aspect of this invention, there is provided a circuit board characterized by comprising at least a composite material as recited in any one of the first to the fifteenth aspects, and the eighteenth aspect.

According to a twenty-second aspect of this invention, there is provided a circuit board characterized by comprising at least a composite material produced by the manufacturing method as recited in the sixteenth or the seventeenth aspects.

### Advantageous Effects of the Invention

This invention provides a composite material comprising particulates dispersed in an insulating material, in which the particulates are allowed to exhibit desirable dispersibility in the insulating material by previously coating the particulates with an insulating material having substantially the same composition as that of the coating insulating material. Therefore, this material can be applied as a material for circuit boards and electronic components so that it is made possible to realize further reduction of size and power consumption of information and telecommunication equipment in a frequency band of several hundred MHz to one GHz.

### BRIEF DESCRIPTION OF THE DRAWINGS

FIG. 1 is a graph representing complex permeability of a composite material according to Example 1 of this invention;

FIG. 2 is an electron micrograph showing a cross section of the composite material according to Example 1 of the invention;

FIG. 3 is a graph representing complex permeability of a composite material according to Comparative Example 1 of this invention; and

FIG. 4 is an electron micrograph showing a cross section of the composite material according to Comparative Example 1 of the invention.

### BEST MODE FOR CARRYING OUT THE INVENTION

This invention will be described in further detail.

A composite material according to this invention contains an insulating material and particulates dispersed in this insulating material.

First, the particulates constituting the composite material according to this invention will be described.

The particulates are made of an organic or inorganic substance. The inorganic substance may be, for example, a magnetic material, while a wide variety of materials such as a dielectric material or glass may be employed as the inorganic substance. When the magnetic material is metal powder, it may comprise at least one of iron (Fe), nickel (Ni), cobalt (Co), an iron (Fe) base alloy, a nickel (Ni) base alloy, and a cobalt (Co) base alloy.

In addition to the foregoing materials, aluminum (Al), manganese (Mn), silicon (Si), magnesium (Mg), chromium (Cr), molybdenum (Mo), copper (Cu), zinc (Zn), tin (Sn), silver (Ag), titanium (Ti) and zirconium (Zr), for example, may be used.

The alloy may be, for example, nickel (Ni), permalloy (Ni—Fe), iron (Fe), iron (Fe)-silicon (Si) alloy, iron (Fe)-nitrogen (N) alloy, iron (Fe)-carbon (C) alloy, iron (Fe)-boron (B) alloy, iron (Fe)-phosphorus (P) alloy, iron (Fe)-aluminum (Al) alloy, or iron (Fe)-aluminum (Al)-silicon (Si) alloy.

If a second component (in case of an alloy, a third and fourth components) is (are) to be contained, it (they) may be, for example, titanium (Ti), vanadium (V), chromium (Cr), manganese (Mn), cobalt (Co), copper (Cu), zinc (Zn), niobium (Nb), molybdenum (Mo), indium (In), or tin (Sn).

When the particulates are made of a metal oxide, it may be a ferrite compound such as goethite (FeOOH), hematite (Fe₂O₃), magnetite (Fe₃O₄), manganese (Mn)-zinc (Zn) ferrite, nickel (Ni)-zinc (Zn) ferrite, cobalt (Co) ferrite, manganese (Mn) ferrite, nickel (Ni) ferrite, copper (Cu) ferrite, zinc (Zn) ferrite, magnesium (Mg) ferrite, lithium (Li) ferrite, manganese (Mn)-magnesium (Mg) ferrite, copper (Cu)-zinc (Zn) ferrite, and manganese (Mn)-zinc (Zn) ferrite.

The powder to be actually used may be selected appropriately from the aforementioned powders by a person skilled in the art according to a use of final electronic equipment.

The aforementioned particulates preferably have a particle size of 0.001 to 10 μm. When the particulates are of a magnetic material, the magnetic flux density thereof will become short due to generation of super-paramagnetism or the like if the average particle size is less than 0.001 μm. On the other hand, if the average particle size exceeds 10 μm, the eddy current loss is increased and the magnetic properties in a high frequency range will be deteriorated.

The shape of the aforementioned particulates may be spherical, elliptical, flat, rod-shaped, amorphous, or hollow. A flat shape is particularly preferable in the case of a composite magnetic material having a high magnetic permeability and low magnetic loss.

When the particulates are of a flat shape, it is desirable that the particulates have a thickness of 0.001 to 5 μm, a length of 0.002 to 10 μm, and an aspect ratio (length/thickness) of 2 or more. This is because if the aspect ratio is smaller than 2, the demagnetizing factor of the powder will be increased, possibly leading to deterioration in relative permeability of the composite material.

The content of the particulates contained in the composite material is preferably 10% or more by volume. This is because if the content is less than 10% by volume, no effect of magnetic powder is obtained and the material does not have enough magnetic properties.

Next, the insulating material constituting the composite material according to this invention will be described.

Any appropriate insulating material commonly used in the field of electronic components such as circuit boards can be used as the insulating material according to this invention. More specifically, when the composite material is used as a material for circuit boards, it is preferred that the material has a low permittivity in view of increasing the characteristic impedance. Therefore, as the insulating material, a synthetic resin having a low permittivity can be suitably selected from resins including, a polyimide resin, a polybenzoxadole resin, a polyphenylene resin, a poly(benzocyclobutene) resin, a poly(arylene ether) resin, a polysiloxane resin, an epoxy resin, an urethane resin, a polyester resin, a polyester urethane resin, a fluororesin, a polyolefin resin, a poly(cycle-olefin) resin, a cyanate resin, a polyphenylene ether resin, and a polystyrene resin.

When a resin is used, the resin may be either a thermoplastic resin or a thermosetting resin.

On the other hand, when high permittivity characteristics are required as in the case of capacitors or antenna elements, ceramics such as Al₂O₃, SiO₂, TiO₂, 2MgO.SiO₂, MgTiO₃, CaTiO₃, SrTiO₃, BaTiO₃, 3Al₂O₃.2SiO₂, ZrO₂, SiC, or AlN, or a mixture of any of these inorganic substances and an organic substance can be used as necessary.

Next, desirable physical properties of the composite material will be described.

Physical properties of the composite material are determined as required by a person skilled in the art according to the use of final electronic equipment, whereas the permittivity may differ between a vertical direction and a parallel direction with respect to an electric field applied during use.

It is desirable that the composite material has a volume resistivity of 5×10⁵ Ω·cm or more.

This is because if the volume resistivity is less than 5×10⁵ Ω·cm, it facilitates the flow of a conduction current, resulting in increased loss due to the conduction current.

The manufacturing method of the composite material according to this invention is not limited to any particular one provided that the composite material has the aforementioned composition, but a preferred manufacturing method is as described below.

Firstly, description will be made of a process of previously coating particulates with an insulating material and then dispersing them in the insulating material.

This process includes the step of obtaining particulates coated with an insulating material by stirring the particulates in a solvent having the insulating material dissolved therein, and the step of dispersing the obtained particulates coated with the insulating material in an insulating material having substantially the same composition as that of the coating insulating material.

When the shape of the particulates is flat, the particulates may be flattened by applying a mechanical force to the particulates while stirring.

Examples of devices, that can be used when stirring the particulates in a solvent comprising the insulating material dissolved therein and in the step of dispersing the particulates coated with the insulating material in an insulating material, include those for applying a mechanical force, such as a ball mill, a mix rotor, an ultrasonic mixer, a bead mill, a kneader and a Fillmix disperser, while a sand mill, a ball mill, or a planetary ball mill is suitable in order to use a dispersion medium according to this invention.

The dispersion medium may be selected, for example, from metals such as aluminum, steel, and lead, or metal oxides thereof, oxide sintered bodies such as alumina, zirconia, silicon dioxide, and titania, nitride sintered bodies such as silicon nitride, silicide sintered bodies such as silicon carbide, and glasses such as soda glass, lead glass, and high-density glass.

Next, a method of applying the slurry thus obtained will be described. The slurry can be formed into an arbitrary sheet shape by a known forming method such as a press molding method, a doctor blade method or an injection molding method so that a dry film is fabricated. Among the above-mentioned methods, the doctor blade method is preferred to form the slurry into a sheet shape in order to form a laminated body of the composite material. In order to adjust the viscosity of the slurry to a suitable level for the above-mentioned application method, the solvent is volatized to increase the concentration before applying the slurry.

Finally, the dry film thus obtained is heat treated or press molded in a reducing atmosphere or a vacuum, whereby a composite material can be obtained in which particulates are uniformly dispersed in the insulating material.

The most significant characteristic of the manufacturing process according to this invention resides in that, in a composite material consisting of an insulating material and particulates, the dispersibility of the particulates in the composite material is improved by previously coating the particulates with an insulating material. The composite material thus obtained exhibits a high magnetic permeability (μ′) and a low magnetic loss (tan δ) even at a high frequency. More specifically, the relative permeability μr is greater than one and the loss factor tan δ is 0.05 or less at a frequency of 1 GHz.

The application of the composite material of this invention described above as a material for a circuit boards and/or an electronic component makes it possible to realize further reduction of size and power consumption of information and telecommunication equipment in a frequency band of several hundred MHz to 1 GHz.

### EXAMPLES

Next, examples according to this invention will be described.

Although this invention will be described more particularly on the basis of Example 1, this invention is not limited to Example 1.

### Example 1

Permalloy magnetic powder comprising a metal element added thereto and having an average particle size of 0.25 μm was mixed in a dispersion liquid in which a polyolefin resin diluted to 33% solid content was dissolved in four-to-one mixture liquid of xylene and cyclopentanone, as an organic compound for forming a coating layer, and then zirconia beads having an average particle size of 200 μm were added as a dispersion medium. Planetary stirring was performed on this mixture for 60 minutes to obtain slurry of particulates coated with the insulating material.

Next, the obtained slurry of insulation-coated particulates (in the state of slurry without being dried) was mixed for five minutes with the polyolefin resin with 40% solid content by planetary stirring using the zirconia beads. The mixture was left stand to precipitate the dispersion medium (although the magnetic powder has a specific gravity of 7 to 8 and zirconia has a specific gravity of 6 to 7, the zirconia beads are precipitated because zirconia beads having a particle size of 200 μm are heavier than the magnetic powder having a particle size of 0.25 μm). The supernatant liquid was introduced into a rotary evaporator, where the solvent was evaporated under a reduced pressure of 2.7 kPa at 50° C. (the reduced pressure lowers the boiling point of the solvent) to obtain a magnetic paste. The obtained magnetic paste was applied and formed on a substrate by using a doctor blade having a gap of 800 μm, and then dried at a normal temperature to fabricate a dry film with a thickness of 50 μm. Three thus-obtained dry films were stacked and press-sintered with a reduced-pressure pressing apparatus. The pressing conditions were such that the temperature was raised up to 130° C. in 20 minutes while keeping the pressure at the normal pressure, and then a pressure of 2 MPa was applied and this state was held for 5 minutes. Thereafter, the temperature was raised up to 160° C. and held for 40 minutes to cure the resin. Thus, a composite material was fabricated with an area of 50 mm×50 mm and a thickness of 150 μm.

The complex permeability of this composite material was measured by a parallel-line method using a Vector Network Analyzer 8719ES made by Agilent.

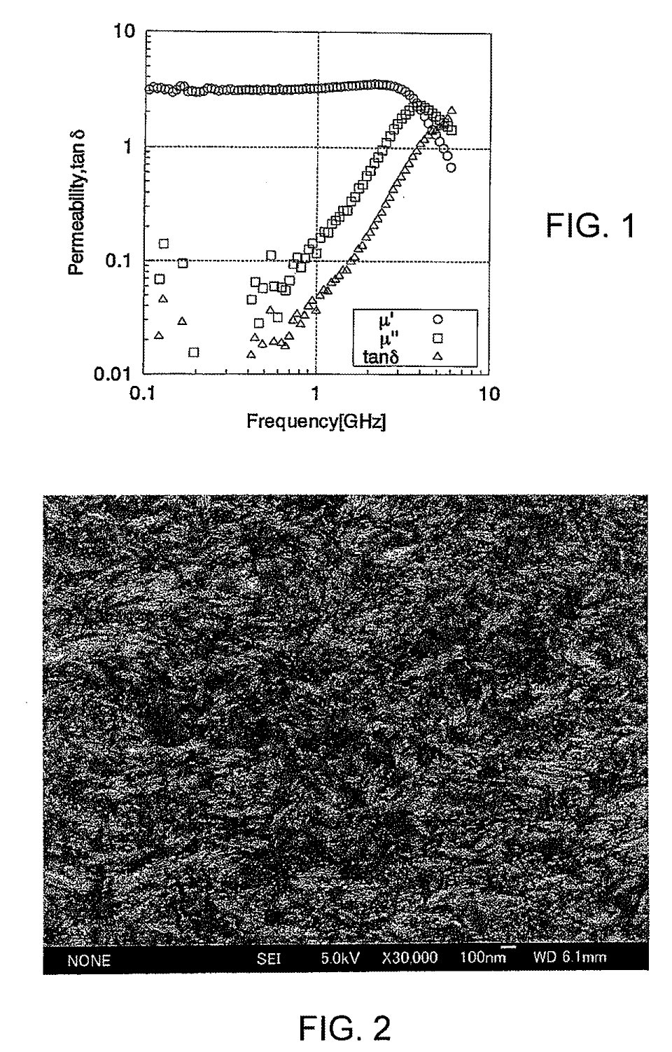

The parallel-line method is a method of measuring the complex permeability using a parallel-plate type transmission line. An example is disclosed in Journal of the Magnetics Society of Japan, vol. 17, p 497 (1993). The measurement result showed that the relative permeability μr was 2.71 and the magnetic loss tan δ was 0.027 at 1 GHz (see FIG. 1). The permittivity was measured by a cavity resonator perturbation method to find that the relative permittivity was 29.2, and the dielectric loss tan δ was 0.037.

Next, a cross-sectional surface of this composite magnetic material was mechanically polished and then observed with the use of a scanning electron microscope JSM-6700F made by JEOL Ltd (Nihon Denshi Kabushiki Kaisha).

An electron micrograph showing a cross-sectional structure of this composite magnetic material is shown in FIG. 2. It was found that the composite material was composed of magnetic powder of a flat shape with a thickness of 50 nm and a length of 200 nm.

### Comparative Example 1

Comparative Example 1 corresponds to Example 1 except that the insulation coating with an organic compound according to this invention was not performed. Four-to-one mixture liquid of xylene and cyclopentanone was mixed with a dispersion liquid in which a polyolefin resin was dissolved as a high-molecular polymer for forming a coating layer. Zirconia beads having an average particle size of 200 μm were additionally added to the mixture as a dispersion medium. Planetary stirring was performed on this mixture for 30 minutes to obtain slurry of magnetic powder. Resin varnish obtained by diluting a poly(cycle-olefin) resin to 40% solid content was added to the slurry thus obtained, and mixed by planetary stirring for five minutes. The revolution speed during the planetary stirring was set to 2000 rpm and the rotation speed was set to 800 rpm.

Then, a composite material with a thickness of 50 μm was fabricated under the conditions of Example 1.

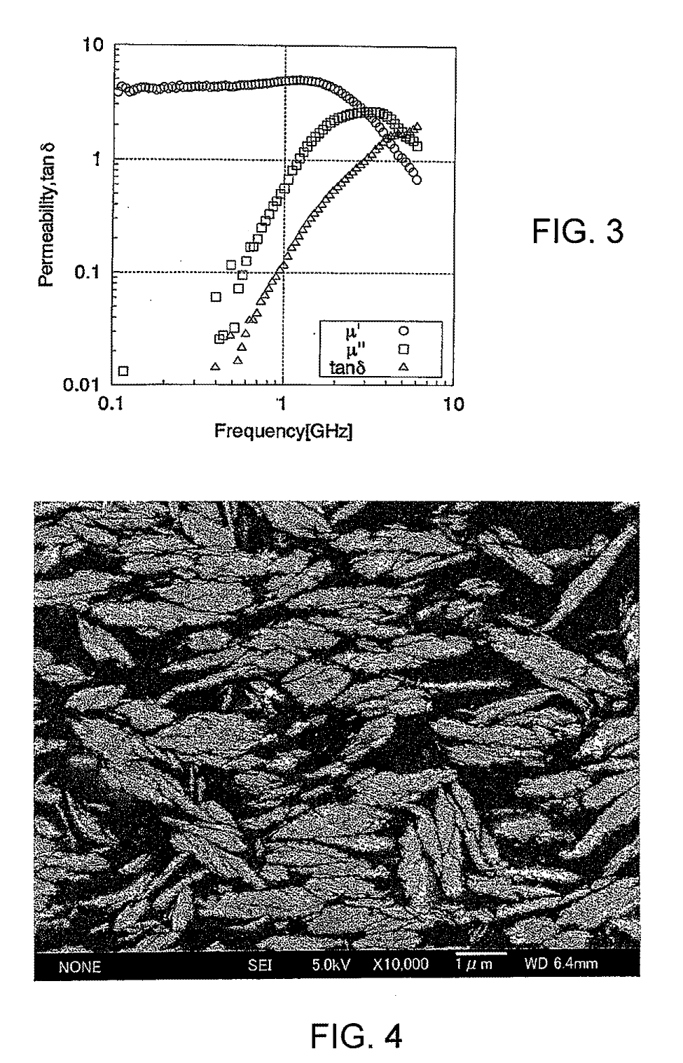

The complex permeability of this composite material was measured by a parallel-line method in the same manner as in Example 1, whereby it was found that the relative permeability pr was 5.62 and the magnetic loss tan δ was 0.186 at 1 GHz (see FIG. 3). The permittivity was measured by a cavity resonator perturbation method to find that the relative permittivity was 58.4 and the dielectric loss tan δ was 0.027.

Then, the cross-sectional structure of this composite magnetic material was observed with an electron microscope in the same manner as in Example 1.

An electron micrograph showing the cross-sectional structure of this composite material (Comparative Example 1) is shown in FIG. 4. The composite material was composed of magnetic powder having a thickness of 200 to 500 nm and a length of 1 to 2 μm. It was found that the particle size was greater than that of Example 1 and the dispersion was less complete than in Example. In other words, it was found that the dispersibility of the magnetic powder of the composite material fabricated according to this invention was higher than that of Comparative Example.

### INDUSTRIAL APPLICABILITY

As seen from the description above, the composite material according to this invention and the manufacturing method thereof are applicable to manufacture of circuit boards, electronic components, electronic equipment, and so on.

1. A composite material having flat particulates dispersed in an insulating material, comprising the flat particulates which have previously been coated with an insulating material having substantially the same composition as that of said insulating material.

2. The composite material as claimed in claim 1, wherein the particulates have a thickness of 0.001 to 5 μm and a length of 0.002 to 10 μm.

3. A composite material having particulates with a particle size of 0.001 to 10 μm dispersed in an insulating material, comprising the particulates with said particle size which have previously been coated with an insulating material having substantially the same composition as that of said insulating material.

4. The composite material as claimed in claim 1 or 3, wherein the particulates comprise at least one member selected from the group consisting of aluminum (Al), manganese (Mn), silicon (Si), magnesium (Mg), chromium (Cr), nickel (Ni), molybdenum (Mo), copper (Cu), iron (Fe), cobalt (Co), zinc (Zn), tin (Sn), silver (Ag), titanium (Ti), and zirconium (Zr).

5. The composite material as claimed in claim 1 or 3, wherein the particulates comprise at least one member selected from the group consisting of nickel (Ni), permalloy (Ni—Fe), iron (Fe), iron (Fe)-silicon (Si) alloy, iron (Fe)-nitrogen (N) alloy, iron (Fe)-carbon (C) alloy, iron (Fe)-boron (B) alloy, iron (Fe)-phosphorus (P) alloy, iron (Fe)-aluminum (Al) alloy, and iron (Fe)-aluminum (Al)-silicon (Si) alloy.

6. The composite material as claimed in claim 4, wherein the particulates are metal powder having added thereto at least one or more metal elements selected from titanium (Ti), vanadium (V), chromium (Cr), manganese (Mn), cobalt (Co), copper (Cu), zinc (Zn), niobium (Nb), molybdenum (Mo), indium (In), and tin (Sn).

7. The composite material as claimed in claim 1 or 3, wherein the particulates comprise at least one member selected from the group consisting of goethite (FeOOH), hematite (Fe₂O₃), magnetite (Fe₃O₄), manganese (Mn)-zinc (Zn) ferrite, nickel (Ni)-zinc (Zn) ferrite, cobalt (Co) ferrite, manganese (Mn) ferrite, nickel (Ni) ferrite, copper (Cu) ferrite, zinc (Zn) ferrite, magnesium (Mg) ferrite, lithium (Li) ferrite, manganese (Mn)-magnesium (Mg) ferrite, copper (Cu)-zinc (Zn) ferrite, and manganese (Mn)-zinc (Zn) ferrite.

8. The composite material as claimed in claim 1 or 3, wherein the amount of the particulates contained in the composite material is 10% or more by volume.

9. The composite material as claimed in claim 1 or 3, wherein the insulating material comprises a thermoplastic resin.

10. The composite material as claimed in claim 1 or 3, wherein the insulating material comprises a thermosetting resin.

11. The composite material as claimed in claim 1 or 3, wherein the insulating material contains a synthetic resin or liquid-phase resin comprising at least one member selected from polyimide resins, polybenzoxadole resins, polyphenylene resins, poly(benzocyclobutene) resins, poly(arylene ether) resins, polysiloxane resins, epoxy resins, urethane resins, polyester resins, polyester urethane resins, fluororesins, polyolefin resins, poly(cycle-olefin) resins, cyanate resins, polyphenylene ether resins, and polystyrene resins.

12. The composite material as claimed in claim 1 or 3, wherein the insulating material comprises at least one member selected from the group consisting of Al₂O₃, SiO₂, TiO₂, 2MgO.SiO₂, MgTiO₃, CaTiO₃, SrTiO₃, BaTiO₃, 3Al₂O₃.2SiO₂, ZrO₂, SiC, and AlN ceramics.

13. The composite material as claimed in claim 1 or 3, wherein, in the composite material having particulates dispersed in an insulating material, the relative permeability μr is greater than one and the loss factor tan δ is 0.05 or less at a frequency of 1 GHz.

14. The composite material as claimed in claim 1 or 3, wherein, in the composite material having particulates dispersed in an insulating material, the composite material has permittivities which differ between a vertical direction and a parallel direction to an electric field applied during use.

15. The composite material as claimed in claim 1 or 3, wherein, in the composite material having particulates dispersed in an insulating material, the composite material has a volume resistivity of 5×10⁵ Ω·cm or higher.

16. A method of manufacturing a composite material comprising the step of producing slurry of flat particulates the surfaces of which are coated with an insulating material by performing the step of mechanically deforming the particulates into a flat shape at the same time with the step of obtaining the flat particulates the surfaces of which are coated with the insulating material, by stirring the particulates in a solvent having the insulating material dissolved therein with the use of a dispersion medium.

17. A method of manufacturing a composite material comprising the step of adding, to slurry of flat particulates the surfaces of which are coated with an insulating material, an insulating material having substantially the same composition as that of the coating insulating material.

18. The composite material as claimed in claim 1 or 3, being manufactured by a manufacturing method comprising the steps of:
obtaining the particulates coated with an insulating material by stirring the particulates in a solvent having the insulating material dissolved therein;
dispersing the obtained particulates coated with the insulating material in an insulating material having substantially the same composition as that of the coating insulating material; and
applying a mechanical force to the particulates to deform the particulates into a flat shape by using a dispersion medium when stirring the particulates in the solvent having the insulating material dissolved therein.

19. An electronic component comprising at least a composite material as claimed in claim 1 or 3.

20. An electronic component comprising at least a composite material produced by the manufacturing method as claimed in claim 16 or 17.

21. A circuit board comprising at least a composite material as claimed in claim 1 or 3.

22. A circuit board comprising at least a composite material produced by the manufacturing method as claimed in claim 16 or 17.
